(19) United States
(12) Patent Application Publication
(10) Pub. No.: US 2011/0014727 A1
(43) Pub. Date: Jan. 20, 2011

(54) THIN FILM PROBE SHEET AND SEMICONDUCTOR CHIP INSPECTION SYSTEM

(76) Inventors: Akira YABUSHITA, Yokohama (JP); Yasunori Narizuka, Hiratsuka (JP); Susumu Kasukabe, Yokohama (JP); Terutaka Mori, Urayasu (JP); Etsuko Takane, Yokohama (JP); Akio Hasebe, Kodaira (JP); Kenji Kawakami, Kai (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/883,982

(22) Filed: Sep. 16, 2010

Related U.S. Application Data
(62) Division of application No. 11/253,575, filed on Oct. 20, 2005.

(30) Foreign Application Priority Data
Oct. 20, 2004 (JP) 2004-306141

(51) Int. Cl. H01L 21/66; H05K 3/02

(52) U.S. Cl. 438/17; 29/847; 257/E21.531

(57) ABSTRACT

In the highly accurate thin film probe sheet which is used for the contact to electrode pads disposed in high density with narrow pitches resulting from the increase in integration degree of semiconductor chips and for the inspection of semiconductor chips, a large spatial region in which a metal film selectively removable relative to terminal metal is formed in advance is formed in the peripheral region around minute contact terminals having sharp tips and disposed in high density with narrow pitches equivalent to those of the electrode pads. Thus, occurrence of damage in an inspection process is significantly reduced, and an inspection device simultaneously achieving the miniaturization and the durability can be provided.

### CROSS-REFERENCE TO RELATED APPLICATION

This application is a divisional application of U.S. application Ser. No. 11/253,575, and which application claims priority from Japanese Patent Application No. JP 2004-306141 filed on Oct. 20, 2004, the contents of which are hereby incorporated by reference into this application.

### TECHNICAL FIELD OF THE INVENTION

The present invention relates to a connection technology employing a probe sheet which is used for the inspection of semiconductor chips. More particularly, it relates to a technology effectively applied to the inspection of semiconductor chips in which minute electrode pads are laid out with narrow pitches or numerous electrode pads can be simultaneously connected.

### BACKGROUND OF THE INVENTION

In the field of the semiconductor module in recent years, the so-called multi-chip module in which semiconductor chips such as LSI and memory are integrated has become more and more popular. This is largely because of the significant improvement in the integration degree of the semiconductor chips resulting from the development of the bare chip technology.

FIG. 15A is a perspective view showing a semiconductor wafer 1 in which numerous semiconductor chips 2 are mutually juxtaposed, and FIG. 15B is a perspective view showing one of the semiconductor chips 2 in an enlarged manner.

Numerous semiconductor chips 2 are formed so as to be mutually juxtaposed on the semiconductor wafer 1, and the semiconductor wafer 1 is divided by dicing into the semiconductor chips 2 to be used. On the surface of the semiconductor chip 2, generally, numerous electrode pads 3 are laid out along the periphery of the chip as shown in the drawing.

Along with the increase in integration degree of semiconductor chips, the pitches of the electrode pads 3 are further narrowed and the density thereof further increases. Under such circumstances, the pitches of the electrode pads are narrowed from about 200 μm or less to, for example, 130 μm, 100 μm or less. Recently, products having pitches close to 50 μm or less are developed.

As the increase in the density of the electrode pads, the pads which used to be laid out in one row are laid out in a plurality of rows along the periphery of the chip and sometimes laid out across the entire surface. Moreover, the tendency to speed up is also significant, and the clock frequencies of microcomputers reach as high as about several GHz.

In order to produce such semiconductor chips and multi-chip modules incorporating them in high yield, technologies for efficient inspection of the electrical properties of the semiconductor chips which is carried out in the last step are required in the manufacturing process of a semiconductor chip.

Conventionally, in a case of semiconductor chips having sufficiently large pad pitches, as a simple inspection probe, inspection means using a probe card of a cantilever method in which tungsten probes obliquely protruding from a wiring board for inspection are orderly disposed has been generally applied.

However, in this method, the reduction in diameter of the probes reaches its limit and cannot catch up with the above-described development of the narrow pitch technology. Therefore, the reduction in diameter has become a bottleneck which increases the overall production cost. By reducing the diameter, durability against scrubbing abrasion required for low resistance contact realized by destructing oxide films on the surface of electrodes is significantly deteriorated, and frequent maintenance is required for maintaining the positional accuracy of the probe tips. Therefore, the cantilever method using tungsten probes has difficulty in the application to the miniaturization.

As the means for solving these problems, which is a simple means for achieving the durability and the miniaturization at the same time and forming highly accurate contact terminals, Japanese Patent Application Laid-Open Publication No. 7-283280 and Japanese Patent Application Laid-Open Publication No. 2002-71719 are proposed, in which thin film probes employing protruding terminals obtained by filling recesses (concavities), which are formed by anisotropic etching of silicon, with a metal film by means of typical photolithography and performing the transfer are used as the measurement means.

FIG. 16 shows a basic structure of a thin film probe card for inspection performed in wafer levels as inspection of qualities such as electrical properties of semiconductor chips.

The illustrated probe card shows an example in which a sheet having a proposed thin film structure for the high density and the narrow pitch is applied. In this example, a thin film probe sheet 44 having minute contact terminals 47 which electrically come into contact with electrode pads of semiconductor chips and attached with a frame 45 is placed with high accuracy on a wiring board 50 composed of a printed board or the like, and a pressing mechanism 39 including a spring probe 42 and a pressing piece 43 is provided for maintaining the low-resistance stable measurement.

FIG. 17 shows a structure example of a thin film probe sheet of conventional technologies utilizing quadrangular-pyramid-shaped concavities formed by anisotropic etching of silicon, and FIG. 18 shows external appearance of the thin film probe sheet 44 in which a polyimide film obtained by sequentially removing a silicon substrate 4 serving as a base material, a thermally oxidized oxide 5, and an undercoat metal film 6 for plating by etching from the structure of FIG. 17 is used as a base material sheet.

The details of the manufacturing process of the above-described thin film probe sheet of conventional technologies are shown in FIG. 19A to FIG. 19F.

For a 100 plane of the silicon substrate 4 which is a single crystal silicon wafer, a pattern region for forming contact terminals is formed by photolithography on the substrate surface on which the thermally oxidized silicon film 5 having a thickness of 0.2 μm is formed, and the substrate is immersed in a mixture of hydrofluoric acid and ammonium fluoride. By doing so, the thermally oxidized silicon film 5 at the openings is etched.

Subsequently, after the resist film is removed, the exposed silicon surface is subjected to anisotropic etching using a high-temperature potassium hydroxide solution with using the thermally oxidized silicon film 5 as a mask. By doing so, quadrangular-pyramid-shaped mold holes 15 are formed. Then, the thermal oxidation process is carried out again to form the thermally oxidized silicon film 5 on the entirety of the base material.

(A) A layered film of chromium and copper is formed by sputtering as the plating undercoat metal film 6. (B) Then, after an arbitrary resist pattern is formed by coating, as contact terminals including the quadrangular-pyramid-shaped mold holes 15, the metal film 47 is formed so as to fill the holes by electroplating, and a polyimide resin to be a base material sheet 7 is applied and thermally cured. Then, through holes 71 for laying out the wirings to predetermined locations are provided therein. (C) In order to provide the through holes 71, for example, laser or reactive dry etching using a metal film pattern as a mask is applied. Furthermore, wiring is formed by a semi-additive method in the same process as the plating film formation of the contact terminals 47. That is, the lead wiring 8 is formed by performing resist patterning, copper plating, and pattern separation. (D) Furthermore, a polyimide resin film 9 is formed by coating as a protective film of the wiring. (E) Furthermore, the thermally oxidized silicon film 5 of the base material, the silicon substrate 4, and the plating undercoat metal film 6 are sequentially removed by etching. In this manner, the thin film probe sheet shown in FIG. 18 is formed.

The above-described process is the same as the process of the method described in Japanese Patent Application Laid-Open Publication No. 7-283280.

### SUMMARY OF THE INVENTION

However, the inventors have found out that the inspection and measurement technologies of semiconductor chips using the above-described probe card involve the following problems.

Due to the downsizing of semiconductor chips and the increasing diameter of semiconductor wafers, the number of semiconductor chips produced from one semiconductor wafer has been increasing, and the time required for inspection thereof has been significantly increasing.

In order to produce a semiconductor chip inspection system applicable to minute electrode pads disposed with narrow pitches, minute contact terminals with narrow pitches equivalent to the electrode pads have to be formed, and the quality of a completed thin film probe sheet having narrow-pitch wirings has to be improved.

In addition, the inspection time can be shortened by forming a pattern which is not only for one chip but also capable of processing a plurality of semiconductor chips at one time in inspection. Nevertheless, it is important in either way to highly accurately form the shape and the positions of the contact terminals.

The above-mentioned Japanese Patent Application Laid-Open Publication No. 7-283280 discloses the following processes. That is, the holes to be the molds for forming contact terminals are formed by anisotropic etching of a 100 plane of a semiconductor wafer, and contact terminals are formed by filling the molds with metal.

An insulating film composed of a polyimide film and lead wiring are separately formed. Moreover, a buffer layer and the silicon wafer to be a substrate are interposed between the insulating film and the wiring board so as to make them integrated, and the molds are removed. Then, the electrode pads of the wiring board are connected to the lead wiring by soldering.

FIG. 20A shows the outline of the formation of quadrangular-pyramid molds by silicon anisotropic etching, and FIG. 20B schematically shows the deposition properties of plating films to the quadrangular-pyramid mold.

The shape of the contact terminal is quadrangular pyramid reflecting the shape of the hole formed in the semiconductor wafer 1. The dimensions of the hole, that is, the processing depths d1 and d2 are determined by etching conditions and the sizes W1 and W2 of the opening which is provided in the thermally oxidized silicon film by photolithography. The hole pitches are naturally determined by the pitches of the openings.

Therefore, when the contact terminal has, for example, a base of 20 μm, quadrangular-pyramid-shaped concavities having a depth of 14 μm are formed, and the pitch of the disposed holes can be controlled for the miniaturization by arbitrarily selecting the size of the base.

In addition, since processing is performed by photolithography and anisotropic etching, the shape and size of the contact terminals can be formed with high accuracy, and in measurement, the oxide film can be destructed only by the pressing movement of the ridge part of the protrusions instead of the scrubbing movement in the conventional technologies mentioned above. Therefore, the inspection in which indentations on the electrode pads are small and contact resistance values are stable can be realized.

However, although a nickel-based material or noble metals are proposed in Japanese Patent Application Laid-Open Publication No. 7-283280 for the formation of the plating metal film which constitutes the contact terminals 47, a hard metal film having excellent abrasion resistance is desired to be applied in order to improve the lifetime of the inspection probe.

However, it is difficult to form a hard metal film with a large thickness due to its large internal stress. In addition, the deposition properties of the plating film to deep mold holes are insufficient in comparison with those to a flat part, and the film thickness tends to be thinner. As a countermeasure for this, some cases employ a structure in which a hard metal film 30 and a subsidiary metal film 31 are stacked as shown in the example of FIG. 20B.

As described above, the structure of the thin film probe sheet in which the contact terminals 47 are formed from the concavities obtained by photolithography and silicon anisotropic etching is excellent in the shapes and position accuracy of the terminals and can sufficiently fulfill the requirements of narrow pitches.

However, in order to realize the miniaturization in which the pitch of the electrode pads of semiconductor chips is down to 100 μm or less, an effective size restriction of the height of the contact terminals 47 is up to about 30 micrometers, and the height is naturally lowered when further narrowing the pitches.

Problems of the inspection process using the thin film probe sheet reside in the property of the surface of the electrodes of semiconductor devices to be measured. More specifically, protrusions due to abnormal deposition of a plating metal film or externally-introduced foreign substances inhibit stable contact, and if the protrusions are large, they cause crucial defects such as squash or deformation of the thin film sheet or the terminals. Therefore, higher terminals are desired although it is contradictory with the narrow pitches.

Japanese Patent Application Laid-Open Publication No. 2002-71719 discloses the contents that have taken these problems into consideration. The method for forming contact terminals by means of transfer from molds utilizing the silicon anisotropic etching is a similar technology. However, the terminals obtained by transfer from the mold in which a plurality of bumps are formed are formed into a cantilever-like shape on another support substrate, and large spaces corresponding to the height of the bumps are formed from the support substrate. Therefore, it is possible to achieve the effects against occurrence of damages due to foreign substances or the like.

In addition, since the contact terminals are supported by means of cantilever support, the scrubbing movement similar to that of a conventional cantilever method can be obtained only by the pressing movement at the contact portion to the electrode pad surface.

However, in the scrubbing contact movement, scratch indentations which are several times larger than those of the fine-sized quadrangular-pyramid tips formed by vertical pressing movement are formed at the contact portion to the pads which have been downsized along with the miniaturization and the adoption of the narrow pitch technology. Accordingly, the reduction of the pad size is restricted, and if packaging by wire bonding performed in the packaging process is taken into consideration, large deformation of the pad surfaces may exert adverse effect on the stable connection.

An object of the present invention is to provide inspection technologies of semiconductor chips applicable to simultaneous connection to numerous electrode pads and electrode pads of a plurality of chips, by use of a probe card comprising a thin film probe sheet in which contact terminals are disposed with narrow pitches which are as narrow as the pitches of the electrode pads, a high density, and high position accuracy.

The above and other objects and novel characteristics of the present invention will be apparent from the description of this specification and the accompanying drawings.

The typical ones of the inventions disclosed in this application will be briefly described as follows.

The present invention is a thin film probe sheet, comprising: a plurality of contact terminals which come into electrical contact with electrodes disposed on a semiconductor chip; individual wirings led out from the contact terminals via through holes of an insulating layer; and a plurality of peripheral electrodes which are electrically connected to the wirings and connected to electrodes of a wiring board, wherein a second metal film which is selectively removable relative to a first metal film which constitutes the contact terminals is disposed in a peripheral region around the plurality of contact terminals, and the second metal film is removed in a post process to provide gaps between the contact terminals, thereby increasing the height of the contact terminals.

Summary of other aspects of the present invention will be briefly described.

The present invention is a thin film probe sheet, comprising: a plurality of contact terminals which come into electrical contact with electrodes disposed on a semiconductor chip; individual wirings led out from the contact terminals via through holes of an insulating layer; and a plurality of peripheral electrodes which are electrically connected to the wirings and connected to electrodes of a wiring board, wherein a base material sheet constituting the thin film probe sheet has a shape in which the regions at which the plurality of contact terminals are to be disposed are recessed in a concave manner from the surrounding region.

Also, the present invention is a thin film probe sheet, comprising: a plurality of contact terminals which come into electrical contact with electrodes disposed on a semiconductor chip; individual wirings led out from the contact terminals via through holes of an insulating layer; and a plurality of peripheral electrodes which are electrically connected to the wirings and connected to electrodes of a wiring board, wherein, of a second metal film disposed in a peripheral region around the plurality of contact terminals, the parts which are formed above the contact terminals are selectively left, and the left second metal film is covered with a resin material constituting an insulating film.

Further, in the thin film probe sheet according to the present invention, the contact terminal has a tip in a shape of a quadrangular pyramid or a truncated pyramid.

Also, in the thin film probe sheet according to the present invention, the contact terminal is made of at least one metal selected from a group including nickel, rhodium, palladium, iridium, ruthenium, tungsten, chromium, copper and tin or composed of laminated films of alloy of the metals.

Further, in the thin film probe sheet according to the present invention, the second metal film is made of at least one metal selected from nickel, copper and tin.

Also, the present invention is a thin film probe sheet, comprising: a plurality of contact terminals which come into electrical contact with electrodes disposed on a semiconductor chip; individual wirings led out from the contact terminals via through holes of an insulating layer; and a plurality of peripheral electrodes which are electrically connected to the wirings and connected to electrodes of a multilayer wiring board, wherein, of a second metal film disposed in a peripheral region around the plurality of contact terminals, the metal film selectively left above the contact terminals has a shape of a polygonal or columnar pillar, and the depth or height of a recess of a spatial region in which the second metal film selectively removed relative to a first metal film which constitutes the contact terminals has been removed is sufficiently larger than the height of a quadrangular pyramid part or a truncated pyramid part formed in advance, thereby increasing the height of the contact terminals.

Further, in the thin film probe sheet according to the present invention, a wiring board on which the thin film probe sheet is mounted and pressing means for applying a pressing force are provided.

In addition, in another aspect of the present invention, the probe card having the structure of the above-described thin film probe sheet is mounted in a semiconductor chip inspection system. According to the semiconductor chip inspection system, the film thickness of the second metal film which is selectively removed relative to the first metal film constituting the contact terminals in a post process is arbitrarily selected, and a large spatial region is provided in the polyimide sheet which is a base material sheet. By doing so, occurrence of damage due to foreign substances externally introduced during the inspection process can be reduced as much as possible.

In addition, even for the minute products in which electrode pad pitch is below 50 μm, a height which is practically equivalent to the height of the conventional contact terminals can be maintained if the depth of the mold holes formed by the anisotropic etching of silicon is made shallow. Therefore, improved effects of deposition properties of the plating metal film constituting the contact terminals can be achieved, and narrow-pith and long-life inspection can be achieved.

### BRIEF DESCRIPTIONS OF THE DRAWINGS

FIG. 1 is a drawing of the entire cross-sectional structure of a thin film probe sheet according to a first embodiment of the present invention;

FIG. 2A is an explanatory drawing illustrating the manufacturing process of the thin film probe sheet of FIG. 1;

FIG. 2B is an explanatory drawing illustrating the manufacturing process of the thin film probe sheet of FIG. 1;

FIG. 2C is an explanatory drawing illustrating the manufacturing process of the thin film probe sheet of FIG. 1;

FIG. 2D is an explanatory drawing illustrating the manufacturing process of the thin film probe sheet of FIG. 1;

FIG. 2E is an explanatory drawing illustrating the manufacturing process of the thin film probe sheet of FIG. 1;

FIG. 2F is an explanatory drawing illustrating the manufacturing process of the thin film probe sheet of FIG. 1;

FIG. 2G is an explanatory drawing illustrating the manufacturing process of the thin film probe sheet of FIG. 1;

FIG. 3 is an explanatory drawing illustrating the relation between the cross-sectional structure and the outline shape of the thin film probe sheet of FIG. 1;

FIG. 4 is a cross-sectional schematic drawing illustrating the detailed structure of the contact terminals in the part A of FIG. 3;

FIG. 5 is a schematic drawing of the cross section showing the outline of the plating deposition properties to a silicon mold hole of a contact terminal according to a second embodiment of the present invention;

FIG. 6A is a structural drawing showing arrangement of a thin film probe sheet of a third embodiment of the present invention and electrode pads of a semiconductor device for a liquid crystal display panel;

FIG. 6B is a structural drawing showing arrangement of a thin film probe sheet of a third embodiment of the present invention and electrode pads of a semiconductor device for a liquid crystal display panel;

FIG. 6C is a structural drawing showing arrangement of a thin film probe sheet of a third embodiment of the present invention and electrode pads of a semiconductor device for a liquid crystal display panel;

FIG. 6D is a structural drawing showing arrangement of a thin film probe sheet of a third embodiment of the present invention and electrode pads of a semiconductor device for a liquid crystal display panel;

FIG. 7A is a plan view showing the relation in the arrangement of the electrode pads and the contact terminals of the third embodiment of the present invention;

FIG. 7B is a schematic drawing of a cross section showing the plating deposition state of the electrode pad of the semiconductor device in which an Au bump is formed;

FIG. 8 is a schematic plan view showing problems of a thin film probe sheet according to a fourth embodiment of the present invention;

FIG. 9A is a plan view in which dummy wiring is formed in the vicinity of the contact terminals in the thin film probe sheet of FIG. 8;

FIG. 9B is a schematic drawing of the wiring configuration;

FIG. 9C is a schematic drawing of the wiring configuration;

FIG. 10 is a schematic drawing in which the dummy wiring and support metal are formed in the contact terminal region in the thin film probe sheet of FIG. 8;

FIG. 11A is a schematic drawing showing an example of a thin film probe sheet according to a fifth embodiment of the present invention in which contact terminals of the thin film probe sheet are connected;

FIG. 11B is a schematic drawing showing an example of a thin film probe sheet according to a fifth embodiment of the present invention in which contact terminals of the thin film probe sheet are connected;

FIG. 12 is a cross-sectional drawing showing the structure of a probe card for inspection in which the thin film probe sheet of FIG. 11A and FIG. 11B is mounted;

FIG. 13 is a cross-sectional drawing showing the entire outline of a semiconductor chip inspection system in which the thin film probe sheet of FIG. 11A and FIG. 11B is installed;

FIG. 14 is a schematic drawing showing external appearance of inspection performed to a semiconductor chip on which electrode pads are arranged by the semiconductor chip inspection system according to the fifth embodiment of the present invention;

FIG. 15A is a perspective view showing a semiconductor wafer to be inspected in which semiconductor chips are arranged, which is examined by the inventors;

FIG. 15B is a perspective view showing the semiconductor chip;

FIG. 16 is a drawing showing a basic structure of a thin film probe card for inspection which is performed in wafer levels as inspection of qualities such as electrical properties of semiconductor chips of FIG. 15;

FIG. 17 is a cross-sectional drawing showing the entire structure of a thin film probe sheet in the conventional technologies;

FIG. 18 is a view showing the external appearance of the thin film probe sheet of FIG. 17;

FIG. 19A is an explanatory drawing showing the manufacturing process of the thin film probe sheet in conventional technologies;

FIG. 19B is an explanatory drawing showing the manufacturing process of the thin film probe sheet in conventional technologies;

FIG. 19C is an explanatory drawing showing the manufacturing process of the thin film probe sheet in conventional technologies;

FIG. 19D is an explanatory drawing showing the manufacturing process of the thin film probe sheet in conventional technologies;

FIG. 19E is an explanatory drawing showing the manufacturing process of the thin film probe sheet in conventional technologies;

FIG. 19F is an explanatory drawing showing the manufacturing process of the thin film probe sheet in conventional technologies;

FIG. 20A is a cross-sectional view showing a silicon mold hole of the thin film probe sheet of FIG. 17, and outline of plating deposition properties; and

FIG. 20B is a cross-sectional view showing a silicon mold hole of the thin film probe sheet of FIG. 17, and outline of plating deposition properties.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

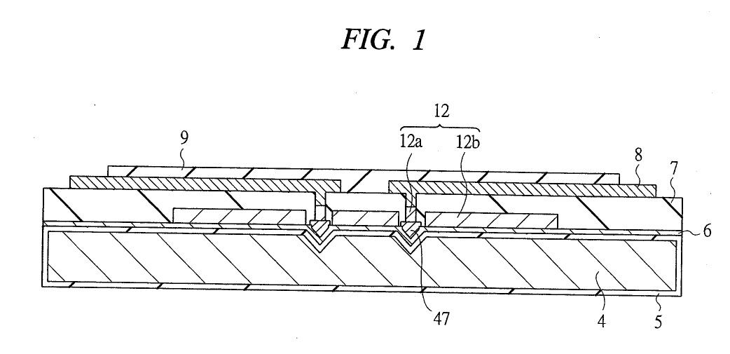

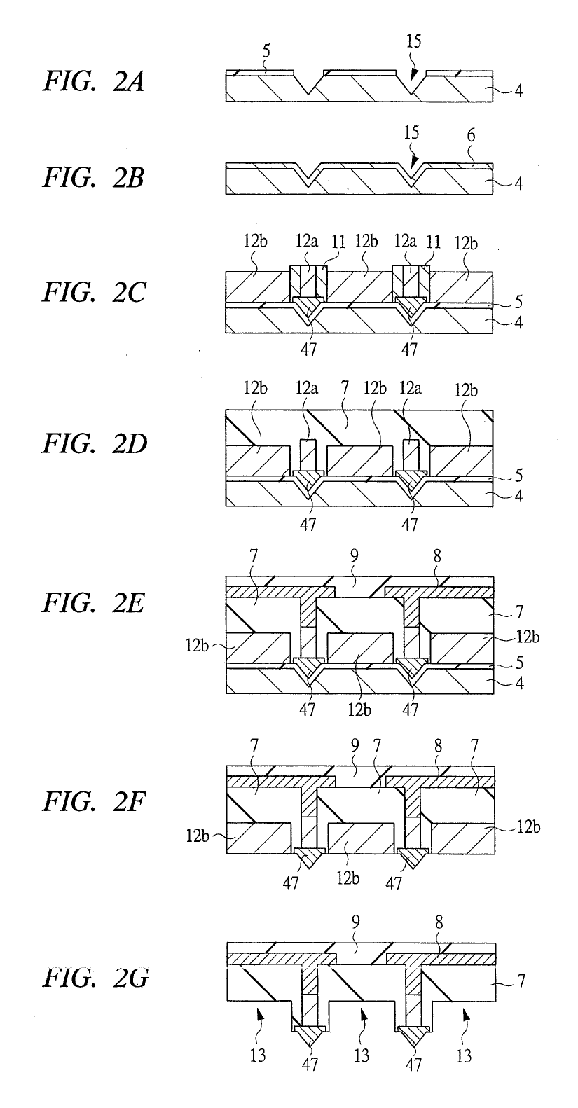

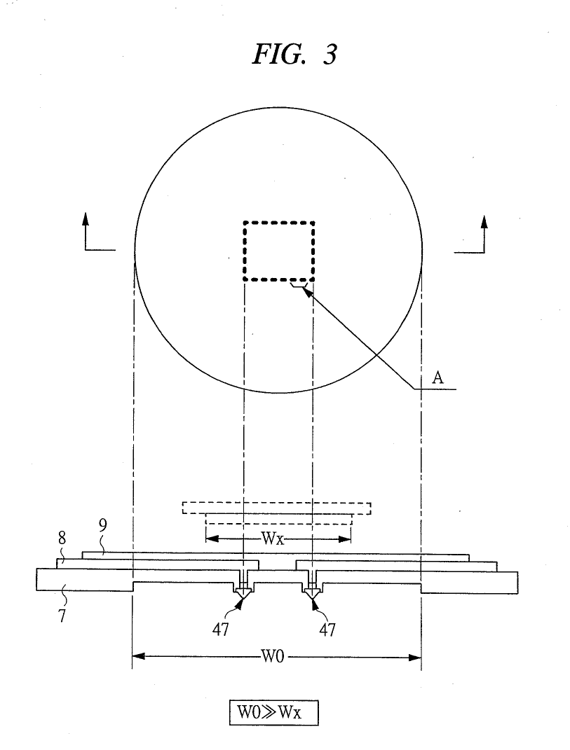

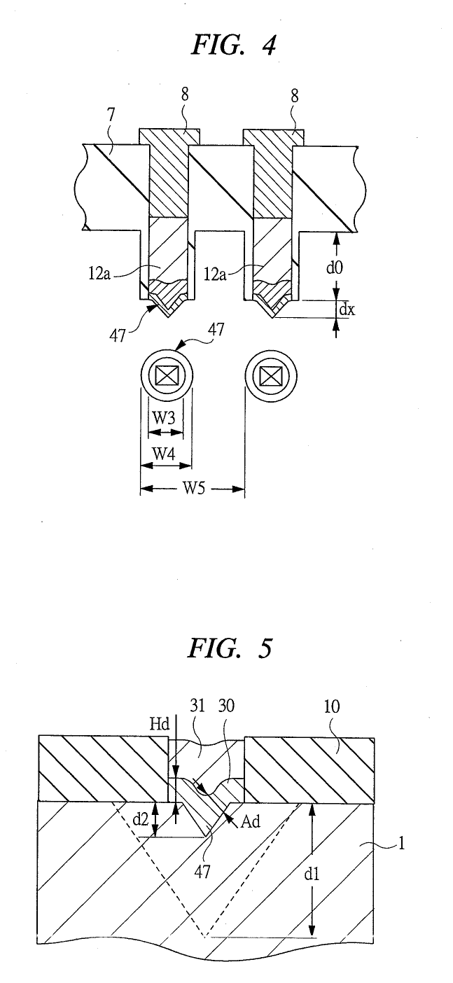

FIG. 1 is a drawing of the entire cross-sectional structure of a thin film probe sheet according to a first embodiment of the present invention. FIG. 2A to FIG. 2G are explanatory drawings illustrating the manufacturing process of the thin film probe sheet of FIG. 1. FIG. 3 is an explanatory drawing illustrating the relation between the cross-sectional structure and the outline shape of the thin film probe sheet of FIG. 1. FIG. 4 is a cross-sectional schematic drawing illustrating the detailed structure of the contact terminals in the part A of FIG. 3.

In the first embodiment, FIG. 1 and FIG. 2 illustrate the manufacturing process of the thin film probe sheet. FIG. 1 illustrates the structure of the thin film probe sheet which is completed through the thin film process on a silicon substrate serving as a base material, and FIG. 2 is a detailed flowchart of the manufacturing process.

For a 100 plane of the silicon substrate 4 which is a single crystal silicon wafer, a pattern region for forming contact terminals is formed by photolithography on the substrate surface on which the thermally oxidized silicon film 5 having a thickness of 0.2 μm is formed, and the substrate is immersed in a mixture of hydrofluoric acid and ammonium fluoride. By doing so, the thermally oxidized silicon film 5 at the openings is etched.

Subsequently, after the resist film is removed, the exposed silicon surface is subjected to anisotropic etching using a potassium hydroxide solution heated to 90° C. with using the thermally oxidized silicon film 5 as a mask. By doing so, quadrangular-pyramid-shaped mold holes 15 are formed.

As a result, a plurality of mold holes 15 of the contact terminals, i.e., openings with a width W1 of 20 μm, have the vertical depth d1 of 14 μm, and arranged with 70 μm intervals are formed. By performing the thermal oxidation process again, the thermally oxidized silicon film 5 is formed on the entirety of the base material.

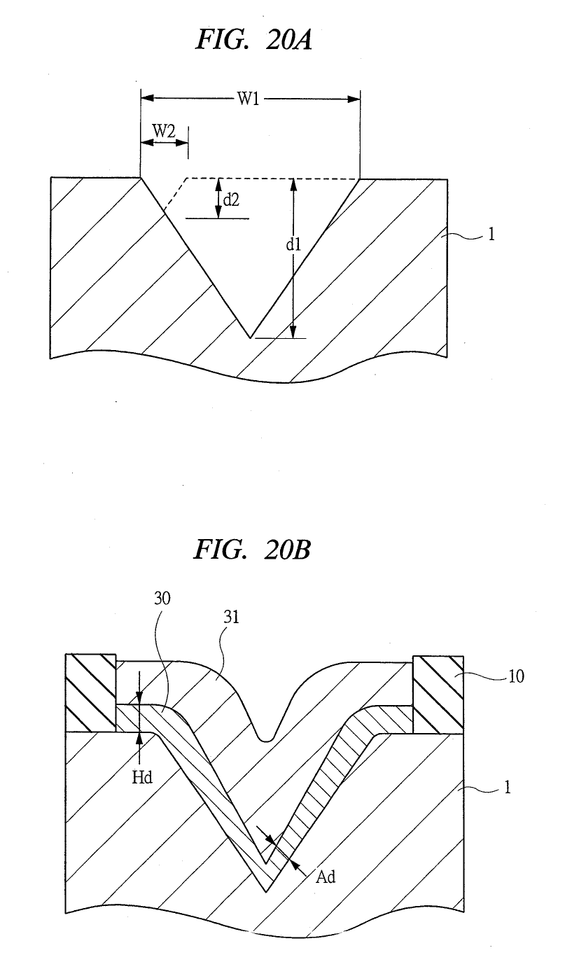

A layered film of chromium (0.1 μm) and copper (0.5 μm) is formed by sputtering as a plating undercoat metal film 6. Then, a resist pattern 10 for forming the contact terminals like that shown in the schematic drawing of FIG. 20B is formed by coating.

The pattern shape is a circle with a diameter of 32 μm which is several μm larger than the diagonal length of the quadrangular prism formed in the previous process, and the thickness of the resist film is 12 μm. Furthermore, metal films that constitute the contact terminals 47 are formed in the quadrangular-pyramid-shaped mold holes 15 so as to fill the holes by electroplating.

The plating films are a hard metal film (first metal film) 30 (FIG. 5) of 4 to 5 μm rhodium and a subsidiary metal film (first metal film) 31 (FIG. 5) of 8 μm nickel. After the resist pattern 10 is removed, a resist pattern 11 for dummy metal films (second metal film) 12a and 12b is newly formed. The dummy metal film 12b is to be selectively removed by etching relative to the contact terminals 47 in a last step.

Next, the pattern shape will be described. That is, the inner and outer diameters of the columnar part of the contact terminals 47 are 32 μm and 40 μm, respectively, the outer diameter of the formation region is 60 mm, and the thickness of the resist film is 20 μm. Also, about 16 μm of copper is formed as the dummy metal film 12 by electroplating.

Furthermore, after the resist pattern 11 is removed, polyimide resin to be a base material sheet is formed by spin coating, and the polyimide resin is heated to 350° C. to be cured. By doing so, an insulating film 7 having a film thickness of 18 μm is formed.

In addition, an aluminum film (film thickness: 2 μm) is formed by sputtering on the polyimide film to form a resist pattern for processing through holes. The aluminum film is etched by a mixed acid mainly containing phosphoric acid, thereby forming the openings in the polyimide insulating film 7. Subsequently, the substrate is irradiated with excimer laser until the nickel film surface of the stacked subsidiary metal film 31 constituting the contact terminals is exposed so as to form through holes in the polyimide film, and the aluminum film is removed by immersing the substrate in a sodium hydroxide solution (not illustrated).

In the similar manner as the former process, films of chromium (0.1 μm) and copper (0.5 μm) are formed by sputtering as a plating undercoat metal film for forming wiring on the polyimide film including the sidewalls of the through holes. Then, by means of a semi-additive method, resist patterning and a copper plating process (film thickness: 10 μm) are carried out, thereby separating the patterns to form the wirings 8.

All of the above-described electroplating solutions are commercially available general-purpose solutions, and the processing conditions are standard conditions.

Furthermore, a polyimide film (film thickness: 6 μm) is similarly formed as a protective film 9 of the wiring 8. As a result, the thin film process on the silicon substrate is completed. Subsequently, in order to separate the polyimide base material sheet, on which the constituent elements are formed in the previous process, from the silicon wafer, the thin film processed surface is first protected, and then, the thermally oxidized silicon film 5 on the underside surface of the silicon substrate 4 is selectively removed by immersing it in a mixture of hydrofluoric acid and ammonium fluoride.

Subsequently, the substrate is put into a potassium hydroxide solution at 90° C. so as to etch the entire silicon wafer. Then, the thermally oxidized silicon film 5 on the upper surface side of the silicon substrate 4 is similarly removed, and subsequently, chromium and copper formed as the plating undercoat metal film 6 are removed by sequentially immersing the substrate in a potassium permanganate solution and a salt iron based etching solution.

Furthermore, the copper formed as the dummy metal film 12b which can be selectively removed relative to the contact terminals 47 is similarly removed by immersing the substrate in a salt iron based etching solution. By doing so, the spatial regions 13 which define the terminal height are formed. As can be seen in FIG. 3, the lower surface of the regions 13 positioned around the peripheral region of each of the contacts 47 will define a terminal height relative to the lower surface of the regions 13 which is higher than a height of the terminal 47 relative to a surface of the insulated film 7 outside of the edges of the regions 13 defined by the width WO.

Details of the main structure of the thin film probe sheet fabricated through the above-described process are shown in FIG. 3 and FIG. 4. FIG. 3 shows the outline of the plane and the cross section of the entirety of the thin film probe sheet, and FIG. 4 shows a detailed cross-sectional structure of the contact terminals in the part A of FIG. 3.

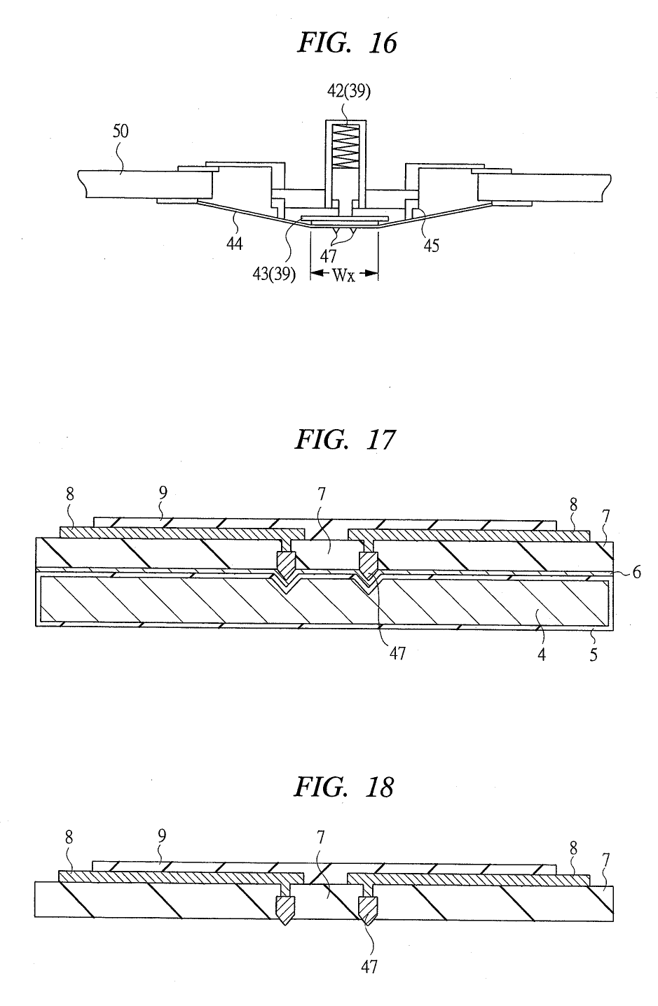

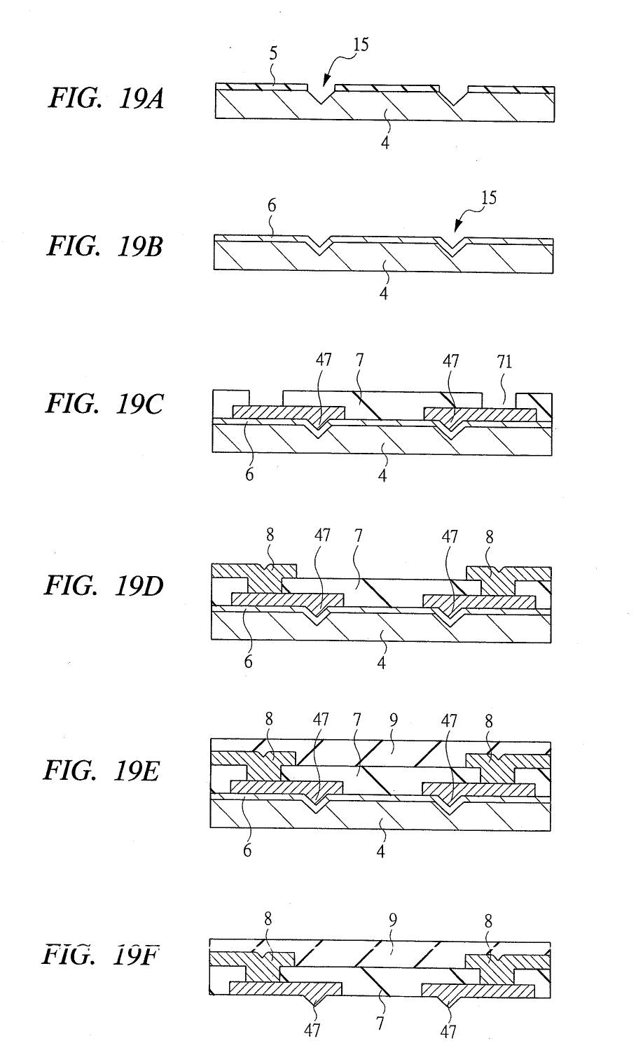

The outer diameter of the formation region W0 of the dummy metal film 12b, which can be selectively removed by etching relative to the contact terminals 47, is 60 mm in the first embodiment. However, as long as the region is sufficiently larger than the size Wx of a pressing piece 43, which constitutes a pressing mechanism 39 of the probe card shown in FIG. 16, the size of the formation region may be arbitrarily set depending on the product.

Moreover, the film thickness d0 of the dummy metal film 12 for forming the spatial region 13 can be increased without any problems. Also, although the structure employing a metal film is described in this embodiment, it goes without saying that other materials can achieve similar effects as long as the film can be selectively removed relative to the metal film constituting the contact terminals and the polyimide film of the base material sheet.

Moreover, although the terminal pitch W5 is 70 μm, the contact terminal diameter W4 is 40 μm, and the space between terminals is 30 μm in the structure of the above-described example, modifications for realizing further narrowed pitches can be made without any problems as long as the resolution of the resist pattern processed by photolithography can be obtained under the processing conditions thereof.

In the thin film probe sheet fabricated in the above-described manner, the large spatial region is formed, which is equal to 30 μm in total including the contact terminal height d1 of 14 μm formed from the mold holes 15 formed by anisotropic etching of silicon and the film thickness d0 of 16 μm of the plating film formed as the selectively removable dummy metal film.

Thus, according to the first embodiment, the factors that cause crucial damage to the minute contact terminals or the nearby thin film sheet due to a foreign substance which has been externally introduced in the chip inspection can be considerably reduced. Therefore, the life can be prolonged, and at the same time, the product cost can be reduced.

### Second Embodiment

FIG. 5 is a schematic drawing of the cross section showing the outline of the plating deposition properties to a silicon mold hole for a contact terminal according to a second embodiment of the present invention.

In the second embodiment, the manufacturing process for further narrowing pitches in a thin film probe sheet having the basically same structure as that obtained by the manufacturing process shown in the above-described first embodiment will be described with reference to FIG. 5.

The process for manufacturing a thin film probe sheet includes: the steps in which the mold holes 15 formed by the anisotropic etching of the silicon substrate 4 which is a single crystal silicon wafer are filled with the hard metal film 30 and the subsidiary metal film 31 constituting the contact terminals 47 by electroplating, and the dummy metal film 12 formed as a means for extending the terminal height is similarly disposed in the adjacent region by electroplating; and the sequentially performed post-steps in which the insulating film 7, the through holes, the wiring 8 and the protective film 9 are formed, the thermally oxidized silicon film 5, the silicon substrate 4 and the plating undercoat metal film 6 are removed by etching, and the dummy metal film 12b is selectively etched, and the process is carried out in the basically same manner as that of the above-described first embodiment (FIG. 2). Consequently, a thin film probe sheet which realizes the measurement of the electrode pads with the pitch of 20 μm is provided.

The shape (depth) of the quadrangular-pyramid-shaped mold hole shown in FIG. 20A obtained by anisotropic etching of silicon is determined by the resist size W1 or size W2 to be processed and etching conditions, and the size is inevitably reduced for the achievement of the narrow pitch.

A plurality of the mold holes 15 for the contact terminals are disposed, in which openings with a width W2 of 5 μm and the vertical depth d2 of 3.5 μm are arranged with intervals of 20 μm. Also, the resist pattern with an outer diameter W3 of 9 μm for forming the contact terminals 47, the contact terminal with a diameter W4 of 13 μm whose outer peripheral surface is covered with the polyimide resin of the insulating film 7, the space between terminals of 7 μm, and the plating-formed film of the dummy metal film 12 with a thickness d0 of 16 μm are formed in the same manner as that of the above-described first embodiment.

In this case, when the metal films constituting the contact terminals 47 are formed to fill the holes by electroplating, the plating film becomes thin at a local recess part in comparison with a flat part, and the deposition properties of uniform film thickness is not obtained in many cases. In the formation of the hard metal film 30 of rhodium when openings with a side of W1 of 20 μm and the vertical depth d1 of 14 μm are formed in the above-described first embodiment, the flat part film thickness Hd is 4 to 5 μm whereas the hole bottom part film thickness Ad is 2 to 3 μm. That is, the film thickness ratio of the hole bottom part to the flat part (Ad/Hd) is about 0.5 to 0.6.

In order to improve the durability (life) of the contact terminals, the hard metal film of rhodium which is good in abrasion resistance is desired to be formed thick. However, this causes such problems as exfoliation of films due to influence of internal stress.

When the vertical depth d2 of the contact terminals is 3.5 μm (¼ compared with conventional case) in the second embodiment, regarding the deposition properties of rhodium of the hard metal film 30 to the quadrangular-pyramid-shaped mold holes 15, the deposition properties obtained for the hole bottom part are equivalent to those of the flat part film thickness Hd of 4 to 5 μm under the same plating conditions (liquid temperature: 55° C., current density: 1 A/dm2, and rhodium concentration: 5 g/L), and the film thickness ratio (Ad/Hd) is significantly improved. This is because the apparent distance between electrodes is in a close state of an equivalent level when the electroplating process is performed and the circulation of the plating solution to be mixed readily forms uniform flow.

The thin film probe sheet thus fabricated has the terminal height of 19 μm in total including the contact terminal height d2 of 3.5 μm formed by the mold holes 15 formed by anisotropic etching of silicon and the film thickness d0 of 16 μm of the plating film formed as the selectively removable dummy metal film. This terminal height is higher than the contact terminal height d1 of 14 μm with the terminal pitch of 70 μm transferred from the quadrangular-pyramid-shaped mold holes in the conventional technologies. Therefore, a thin film probe sheet applicable to the narrow pitch in which a large spatial region is formed can be formed.

Thus, in the second embodiment, the factors that cause crucial damage to the minute contact terminals or the nearby thin film sheet due to a foreign substance externally introduced during the chip inspection are considerably reduced. Therefore, the life can be prolonged, and at the same time, the product cost can be significantly reduced.

### Third Embodiment

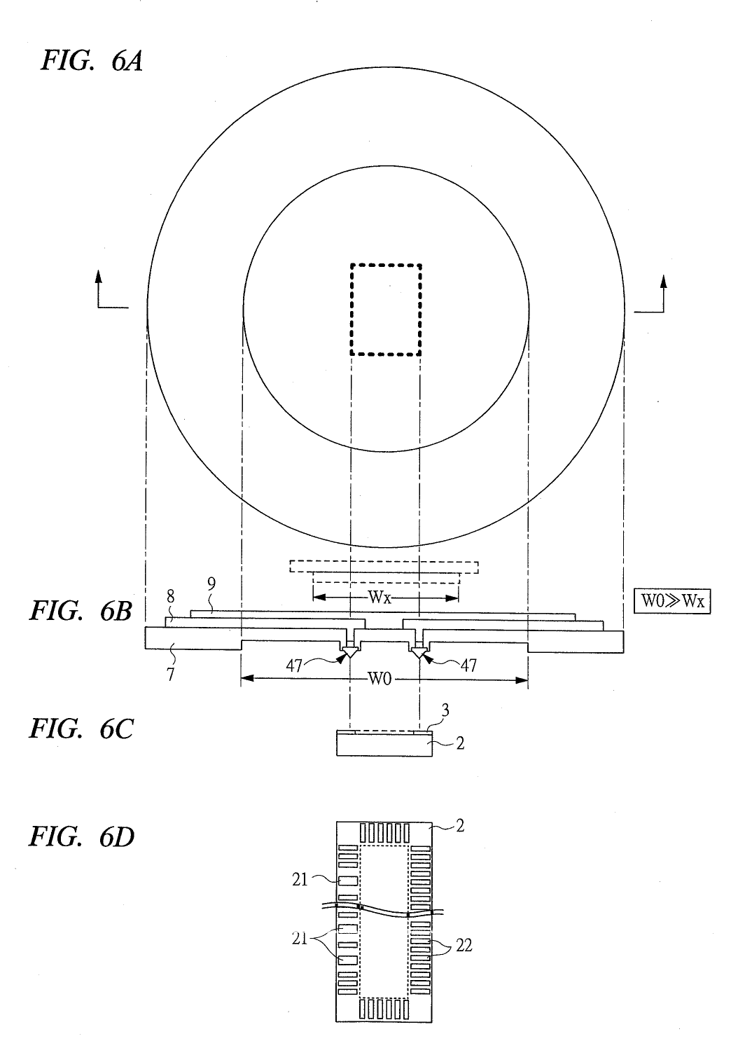

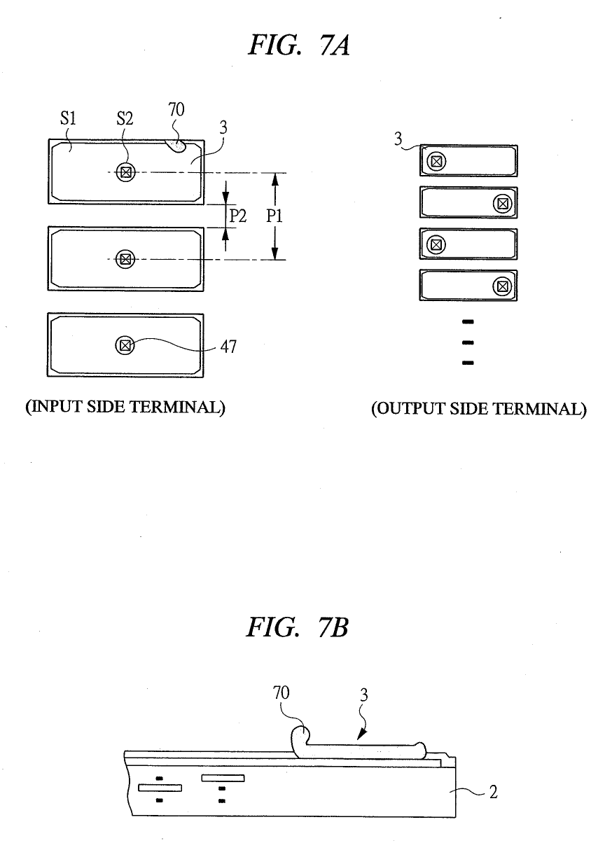

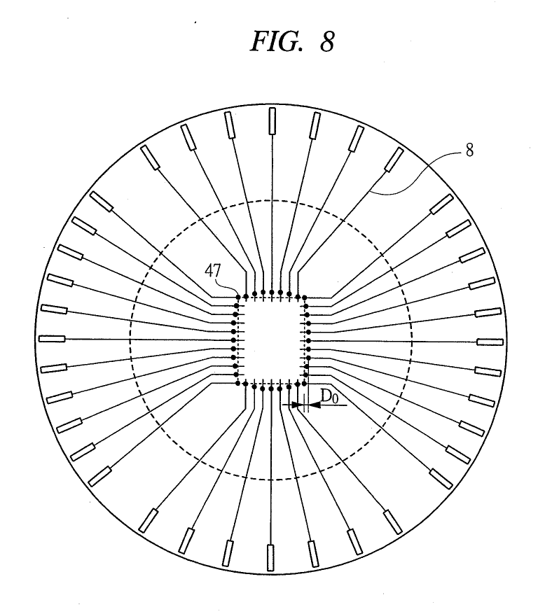

FIGS. 6A to 6D are structural drawings showing arrangement of a thin film probe sheet of a third embodiment of the present invention and electrode pads of a semiconductor device for a liquid crystal display panel. FIGS. 7A and 7B are a plan view showing the relation in the arrangement of the electrode pads and the contact terminals of the third embodiment of the present invention and a schematic drawing of a cross section showing the plating deposition state of the electrode pad of the semiconductor device in which an Au bump is formed.

In the third embodiment, an example of the structure of the thin film probe sheet and a semiconductor chip 2 which is an inspection target is shown in FIG. 6A to FIG. 6D.

FIG. 6A and FIG. 6B are the plan view and the cross-sectional view of the entire sheet shown in FIG. 3, FIG. 6C shows a cross section showing the relation of the electrode pads 3 of the semiconductor chip 2 which is an inspection target facing to the contact terminals, and FIG. 6D shows an example of the planar structure of the inspection target semiconductor chip 2 in which electrode pads 3 are disposed.

In this case, the structure of the thin film probe sheet for inspecting a semiconductor device driver for controlling a liquid crystal display (hereinafter, referred to as a LCD) panel is shown, in which development of narrowing pitches of the electrode pads 3 is significant.

Development such as miniaturization of electrode pitches of LCD drivers down to below 50 μm and increase of wiring density per a chip have been rapidly progressing along with the increase in the number of signal lines resulting from the increase of resolution and size of display panels.

The configuration of the electrode pads 3 of the LCD driver shown in FIG. 6D is an example of a case where input terminals are disposed on the left side part and output terminals are disposed on other three sides in this drawing. Among the pitches of the electrode pads 3, electrode pads 21 on the input terminal side are formed to have relatively large pitches and pad areas because they are used for signal system lines and a power supply system or a ground system, which require comparatively large current capacities. Therefore, since the contact terminals 47 formed on the thin film probe sheet can be arranged to form a layout pattern in which they are aligned in one line, there are few technical problems.

On the other hand, as described above, due to the increase in the number of signal lines and the miniaturization of the pitches down to below 50 μm for electrode pads 22 on the output terminal side for driving signal lines, the contact terminals 47 for the pads 22 have to be disposed with narrow pitches.

An outline of the configuration of the contact terminals 47 of the thin film probe sheet for narrow pitches such as those of the LCD driver is shown in FIG. 7A and FIG. 7B. FIG. 7A is a schematic drawing showing the configuration of the electrode pads, and FIG. 7B shows an example case of a product of the LCD driver in which an Au bump is formed as an electrode pad.

Regarding arrangement of the contact terminals, as shown in FIG. 7A, when the electrode pads 3 and the contact terminals satisfy the relation of S1>>S2 wherein the area S2 of the terminal tip is sufficiently smaller than the pad area S1 and also satisfy the relation of P1>>P2 wherein the electrode pad space P2 is sufficiently smaller than the terminal pitch P1, the terminals for the input side electrode pads 21 can be disposed in one line. On the other hand, the contact terminals 47 for the electrode pads 22 on the output terminal side whose pitches are notably narrowed are arranged in a zigzag manner so as to achieve the contact to the electrode pads 22. In this manner, a narrow pitch terminal array can be achieved.

In the case of a semiconductor device in which Au bumps are formed as electrode pads like in a LCD driver, if the film thickness of generally formed Au bumps is extremely large, a specific protrusion 70 is sometimes formed in consequence of abnormal deposition of plating films. This has to be taken into consideration as a factor other than damage of the terminals due to externally-introduced foreign substances or the like.

The protrusion 70 due to abnormal plating deposition tends to occur in the peripheral region of pads as shown in the drawing, and it sometimes reaches several tens μm.

Thus, in the third embodiment, in the spatial region 13 in the vicinity of the contact terminals 47 of the thin film probe sheet, a large spatial region, in which the dummy metal film 12 which can be selectively removed by etching relative to the contact terminals 47 is formed, is formed in advance. Therefore, the further higher contact terminals 47 are formed, and narrowed pitches and prolonged life can be achieved without causing crucial damage on the minute contact terminals or the sheet surface in the vicinity thereof.

### Fourth Embodiment

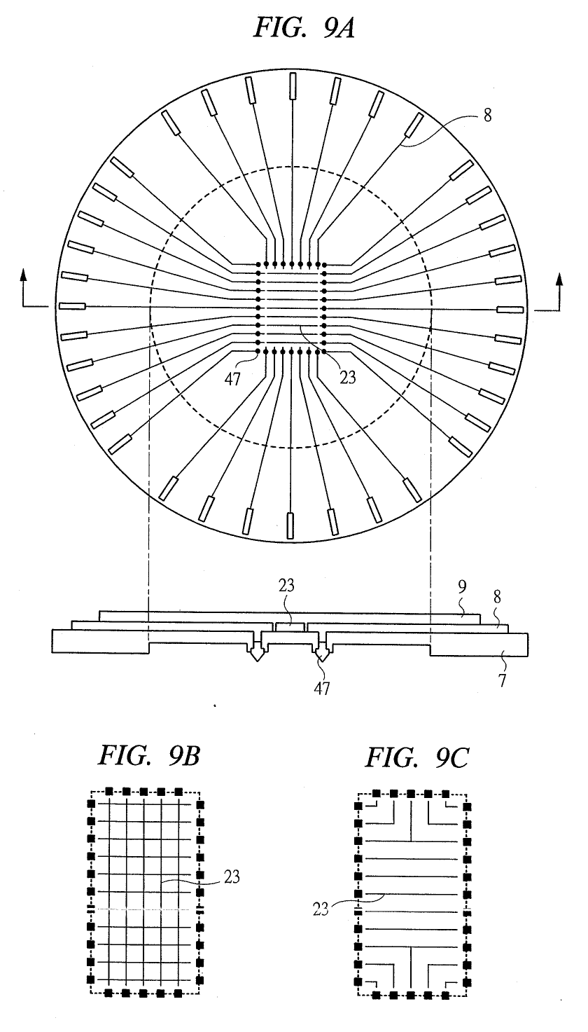

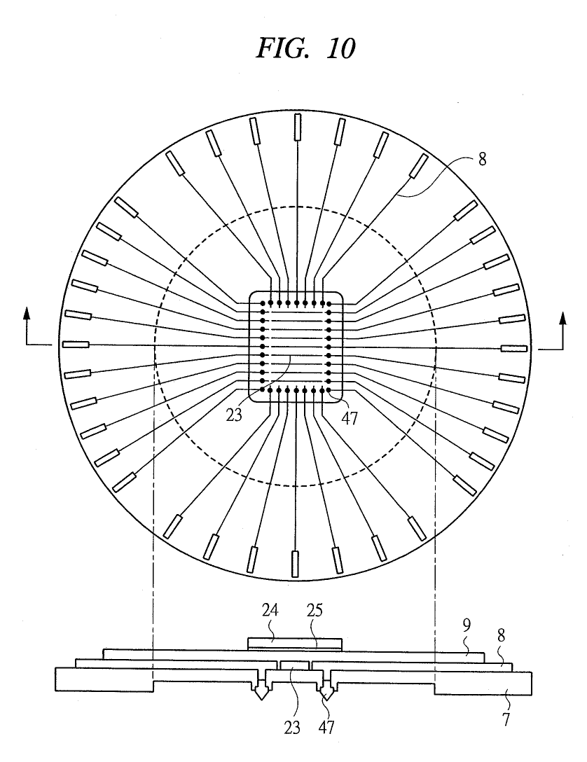

FIG. 8 is a schematic plan view showing problems of a thin film probe sheet according to a fourth embodiment of the present invention. FIG. 9A to FIG. 9C are a plan view in which dummy wiring is formed in the vicinity of the contact terminals in the thin film probe sheet of FIG. 8, and schematic drawings of the wiring configuration. FIG. 10 is a schematic drawing in which the dummy wiring and support metal are formed in the contact terminal region in the thin film probe sheet of FIG. 8.

The fourth embodiment relates to novel sheet structures for improving the position accuracy of the contact terminals 47 of the thin film probe sheet having the structures of the first to third embodiments.

An example of the outline of the plan view of the thin film probe sheet fabricated so as to have the structure of the above-described first to third embodiments and the problems thereof are shown in FIG. 8.

The thin film probe sheet in which wirings 8 uniformly led from the contact terminals 47 to the outer periphery of the sheet are formed is positioned with high accuracy and mounted on a probe card such as that shown in FIG. 16. For a product type in which pitches are notably narrowed like the LCD driver described in the third embodiment, it is important to maintain the position accuracy (pitch, height) of the contact terminals 47 with an accuracy of ±2 μm, and the sheet is assembled with high accuracy so that the contact terminals are aligned with the target electrode pads of the semiconductor device in the state where the pressing mechanism (pressing means) 39 comprising spring probes 42 and the pressing piece 43 applies tension to the sheet with an appropriate pressing amount.

However, as shown in FIG. 8, when the region in which the contact terminals 47 are disposed remains as the polyimide film constituting the base material sheet and a pattern space is present, the sheet is unevenly extended during the adjustment for assembling, and the position of the contact terminal 47 is sometimes misaligned by Do shown in the drawing.

Moreover, at the time of the pressing movement in the inspection, uniform load that is equivalent to the load on the terminal array region in which wirings are formed is not applied thereto due to the influence of the pattern space. Consequently, the accuracy of the height of the contact terminals 47 is degraded.

Moreover, in the property inspection of various types of semiconductor devices by using a semiconductor inspection system, the inspection at a high temperature range of 100° C. or more is sometimes performed depending on the product type. Also in this case, the position of the contact terminal array initially positioned with high accuracy is misaligned due to the thermal behavior of the polyimide film in some cases.

Examples of the structure for maintaining and improving the position accuracy in the sheet plane in the assembling operations are shown in FIG. 9A to FIG. 9C and FIG. 10.

FIG. 9A shows a plan view and a cross section of the entirety of the sheet of FIG. 3, which show a configuration in which dummy wirings are formed in the pattern region of the terminal array. FIG. 9B and FIG. 9C show examples of the configuration of the dummy wirings formed in the pattern region of the terminal array.

FIG. 10 shows a configuration example in which the support metal for maintaining the position accuracy is attached so as to cover the region of the contact terminal array.

The dummy wirings 23 formed in the pattern region of the contact terminal array are formed by plating simultaneously with the step of disposing the lead wiring 8 by the semi-additive method described in conventional technologies or the first embodiment, and arbitrary patterns such as those shown in FIG. 9A to FIG. 9C are formed depending on the product type of the terminal arrays.

By forming the dummy wiring 23, local position misalignment in the above-described assembling process of the thin film probe card is reduced, and the positions of the contact terminals 47 in the pattern plane can be maintained with high accuracy.

Moreover, in order to improve the position accuracy in a high temperature range during the property inspection, as shown in FIG. 10, the support metal 24 is attached so as to cover the region in which the contact terminals 47 are disposed. By doing so, the position accuracy is maintained.

For example, an invar based (nickel-iron) 42 alloy (42 nickel-iron) having a thermal expansion coefficient almost equivalent to that of the silicon base material of the semiconductor device to be inspected is desirable as the support metal 24, and it is directly and evenly attached to the polyimide protective film 9 for the wirings, which is formed in the last step of the thin film process, by an epoxy adhesive.

In this case, a 42 alloy sheet having a thickness of 100 μm is bonded by epoxy Aremco-Bond (produced by Aremco Products, Inc.), and then, the shape including the contact terminal region is further patterned by photolithoetching according to the product type.

According to this structure, a thin film probe sheet in which the contact terminals 47 transferred from a photomask pattern corresponding to the product type are disposed with high accuracy on the silicon substrate can be fabricated. Furthermore, the sheet can be mounted on a probe card while maintaining the accuracy. In addition, regardless of the factors of the property inspection environment during the operation of the semiconductor inspection system, the positions of the contact terminals in the plane can be maintained with high accuracy.

Thus, according to the structure of the thin film probe sheet in the fourth embodiment, the spatial regions 13 in the vicinity of the contact terminals 47 include the large spatial regions in which the dummy metal film 12 which can be selectively removed by etching relative to the contact terminals 47 is formed in advance. Therefore, since the further higher contact terminals 47 are formed, it is possible to achieve the narrower pitches with the improved position accuracy and prolonged life at the same time without causing crucial damage on the minute contact terminals and the sheet surface around them.

### Fifth Embodiment

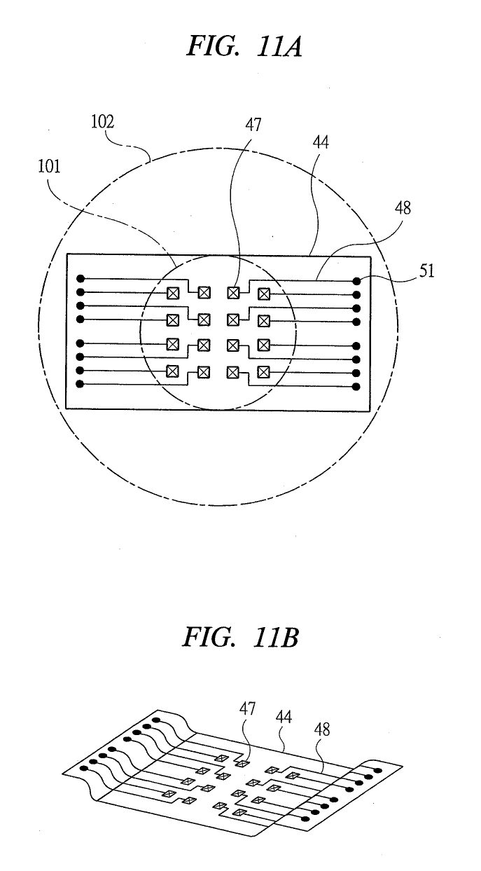

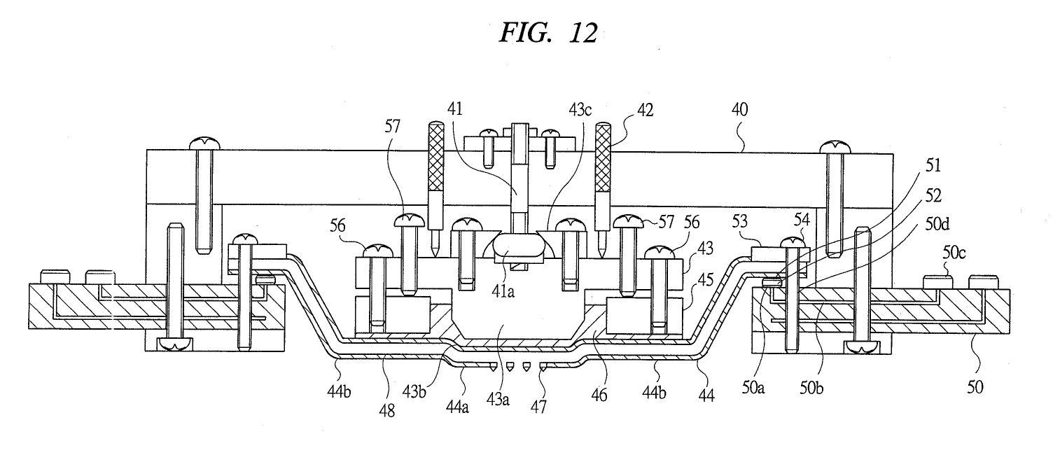

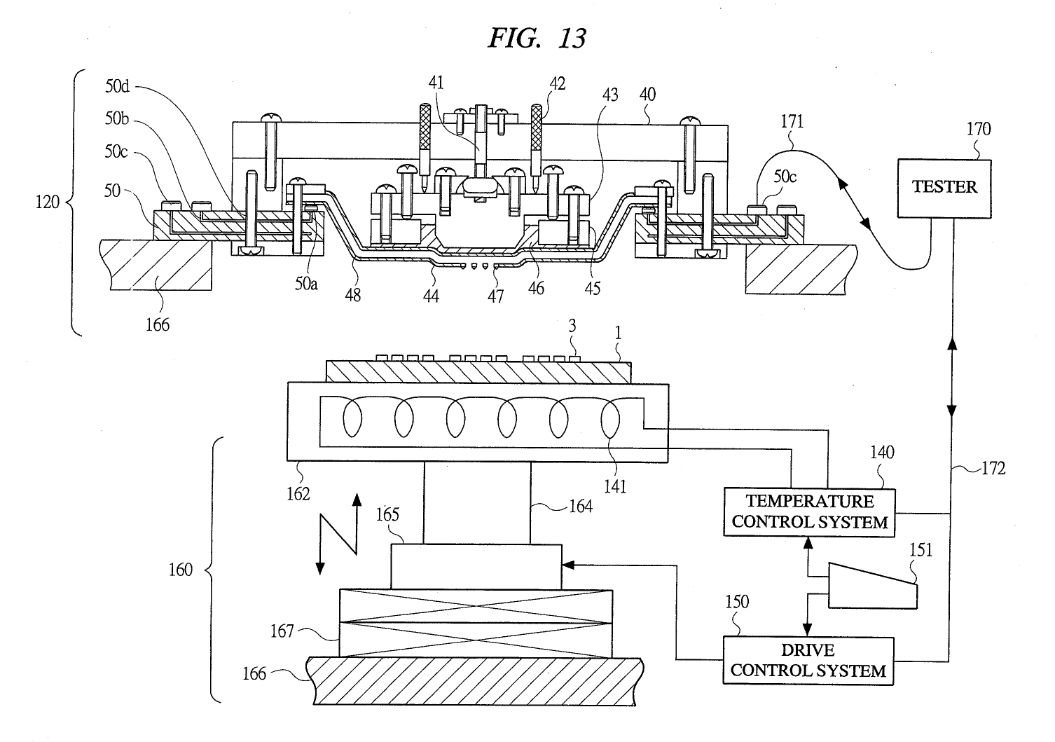

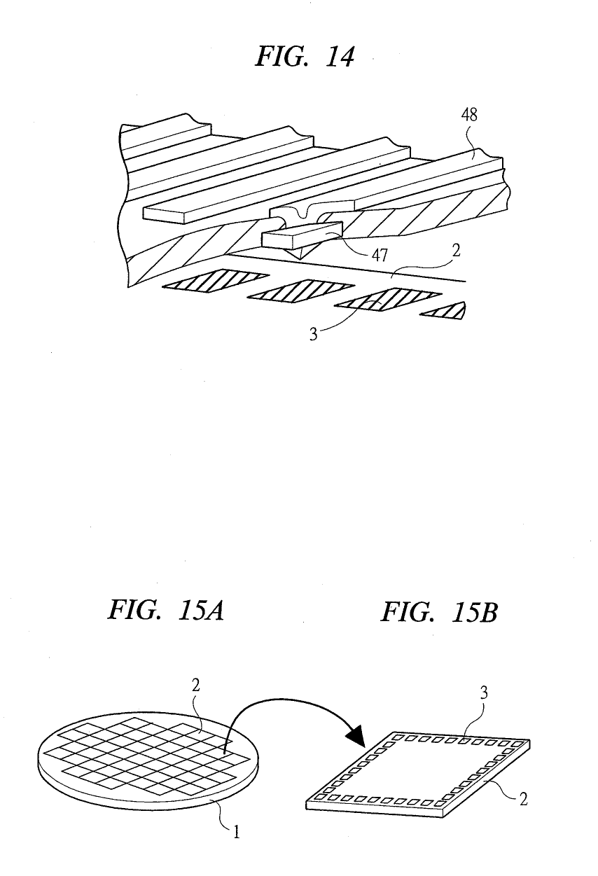

FIGS. 11A and 11B are schematic drawings showing an example of a thin film probe sheet according to a fifth embodiment of the present invention, in which contact terminals of the thin film probe sheet are connected. FIG. 12 is a cross-sectional drawing showing the structure of a probe card for inspection in which the thin film probe sheet of FIG. 11A and FIG. 11B is installed. FIG. 13 is a cross-sectional drawing showing the entire outline of a semiconductor chip inspection system in which the thin film probe sheet of FIG. 11A and FIG. 11B is installed. FIG. 14 is a schematic drawing showing external appearance in the inspection performed to a semiconductor chip on which electrode pads are arranged by the semiconductor chip inspection system according to the fifth embodiment of the present invention.

The fifth embodiment relates to a probe card and a semiconductor inspection system using a thin film probe sheet fabricated according to the above-described first embodiment and the fourth embodiment.

The arrangement of the contact terminals in the thin film probe sheet and the lead wirings to the outer peripheral part of the sheet are configured in various ways depending on the arrangement of the electrode pads on the semiconductor chips 2 which are targets to be inspected.

An example of these is shown in FIG. 11A and FIG. 11B.

FIG. 11A is a plan view of the sheet, and FIG. 11B is a perspective view showing that the sheet on which the wirings are provided is in a bent state. Note that, in this configuration, the number of contact terminals and wirings is reduced in order to simplify the illustration and description, and the density thereof is reduced in the illustration. In a practical case, a large number of the contact terminals are further provided, and they are disposed in a high density.

As shown in the drawings, in the thin film probe sheet, for example, on the sheet wiring board using the polyimide film as a base material, the contact terminals 47 disposed at the positions corresponding to the electrode pads 3 of the semiconductor chips 2 to be inspected are connected to one ends, electrodes 51 are provided at the other ends in the peripheral part of the sheet wiring board, and wirings 48 mutually connecting them are formed.

The wirings 48 can be provided in various patterns. For example, the wirings can be extended in one direction or radially. More specifically, in the example shown in FIG. 11A and FIG. 11B, the sheet wiring board is formed in a rectangular shape, and the electrodes 51 are disposed on both ends.

Also, although the contact terminals are disposed in a plurality of rows and columns in this example, various modifications can be made depending on the product types having different configurations.

For example, in the case where the semiconductor chips to be inspected comprise electrode pads on the surface of the semiconductor chips formed on a semiconductor wafer, the thin film probe sheet for transmitting electric signals to the main unit of the inspection system is fabricated according to the method described in the first and second embodiments by use of a contact terminal forming member 102 such as a silicon wafer one size larger than the region 101 of the wafer in which the semiconductor chip is formed as shown in FIG. 11A. Note that FIG. 11B shows an example in which the sheet 44 is bent so as to enclose the region 101, in which the contact terminals 47 are formed, within a polygon.

Note that the case where the electrode pads of all semiconductor chips formed on a semiconductor wafer are collectively contacted has been described here. However, the present invention is not limited to this. For example, as the thin film sheet for individually inspecting the semiconductor chip or that for inspecting arbitrary number of semiconductor chips at the same time, the wiring board for inspection with a size smaller than the wafer size can be manufactured.

FIG. 12 is a structure drawing showing a main part of the configuration of the probe card in which a thin film probe sheet according to the present invention is incorporated in an inspection connection system.

The connection system comprises an upper clamping plate 40, a center pivot 41 fixed to the plate 40, which is a support axis having a sphere 41a at the lower portion thereof, spring probes 42 as pressing force applying means provided symmetrically around the center pivot 41 and applying a constant pressing force for the upward and downward displacement, a pressing member 43 held so as to be tilted by the tilt 43c to the center pivot 41 and to which the pressing force of a small load (about 3 to 50 mN per pin) is applied from the spring probes 42, the thin film probe sheet, a frame 45 fixed to the thin film probe sheet, a buffer layer 46 provided between the thin film probe sheet and the pressing member (pressing piece) 43, and the contact terminals 47 provided on the thin film probe sheet.

The reason why the spring probes 42 are used to apply the pressing force to the pressing member 43 is to obtain the constant pressing force of small load for the displacement of the tips of the spring probes 42. Therefore, it is not always necessary to use the spring probes 42.

The upper clamping plate 40 is mounted on a wiring board 50. The wiring board 50 is made of, for example, a resin material such as polyimide resin or glass epoxy resin, and it has an internal wiring 50b and connecting terminals 50c.

The electrode 50a is composed of, for example, a via 50d connected to a part of the internal wiring 50b. The wiring board 50 is fixed to the thin film probe sheet by sandwiching the thin film probe sheet between the wiring board 50 and holding members 53 with screws 54.

The thin film probe sheet has a peripheral part outwardly extending over the frame 45 and the extended part is gently bent on the outside of the frame 45 and is fixed to the wiring board 50. At this time, the wiring 48 of the thin film probe sheet is electrically connected to the electrode 50a provided on the wiring board 50. The connection therebetween is made by directly applying a pressure to the electrodes 51 and 50a or by using an anisotropic conductive sheet 52 or solder.

As the buffer layer 46, an elastic material is desirably used, and silicon rubber is shown as an example of the polymeric material with the rubber elasticity. Also, as the buffer layer 46, the structure in which the pressing member 43 is movably sealed to the frame 45 and air is supplied into the gap of the sealing can also be used.

In addition, the buffer layer 46 can be omitted if the height of the contact terminals 47 can be made uniform. Note that, in FIG. 12, the contact terminals 47 and the wirings 48 corresponding to only several contact terminals are shown for the simplification of the description. In a practical case, however, a large number of contact terminals 47 and the wirings 48 are provided.

An object of the thin film probe sheet according to the present invention is to properly connect the contact terminals at small load (3 to 50 mN per pin) simultaneously to the electrode pads 3 made of aluminum or solder or gold bumps, on the surface of which an oxide is formed, with a stably low resistance of about 0.05 to 0.1Ω, in one or plural semiconductor chips of a large number of semiconductor chips in the form of wafer.

By doing so, the scrubbing movement required in the conventional cantilever method becomes unnecessary and the problems of the indentations and the electrode waste due to the scrubbing movement can be prevented.

More specifically, in the thin film probe sheet, the tip portions of the contact terminals 47 arranged so as to correspond to the arrangement of the electrode pads 3 are made sharp, and the region 44a inside the peripheral region 44b in which the contact terminals 47 are arranged is pressed by a lower surface 43b with a precise flatness of a protruding portion 43a (pressing piece) formed in the lower part of the pressing member 43 via the buffer layer 46 so that the region 44a is projected from the peripheral region 44b supported by the frame 45. By doing so, the sagging of the thin film probe sheet is removed. Then, the sharp tips of the contact terminals 47 arranged in the projected region 44a are vertically pressed at small load to the electrode pads 3 made of aluminum or solder or gold bumps. By doing so, the contact terminals 47 easily pass through the oxide formed on the surface of the electrode pads 3 and are brought into contact with the metal conductor material of the electrodes, and the preferable contact therebetween can be secured with a stably low resistance value.

In particular, the region 44a inside the peripheral region 44b in which a number of contact terminals 47 are arranged is pressed by a lower surface 43b with a precise flatness of a protruding portion 43a formed in the lower part of the pressing member 43 via the buffer layer 46 so that the region 44a is projected from the peripheral region 44b supported by the frame 45. By doing so, the sagging of the thin film probe sheet is removed, and the tips of a large number of contact terminals 47 have the same height in accordance with the flatness of the lower surface 43b of the protruding portion 43a.

Note that the projecting amount of the pressing member 43 in the region 44a is defined in accordance with a protrusion of adjustable screws (clinchers) 57, which are fastened at the left, right, back and forth of the pressing member 43 around the center pivot 41, from a lower surface of the pressing member 43.

More specifically, screws 56 inserted into the holes formed at the left, right, back and forth in the holding member around the center pivot 41 are screwed to the frame 45 to let down the protruding portion 43a of the pressing member 43. By doing so, the lower ends of the screws 57 attached to the pressing member 43 with a specified protruding amount are brought into contact with the upper surface of the frame 45 to which the peripheral region 44b of the region 44a in the thin film probe sheet is bonded and fixed.

As a result, the region 44a in which a large number of contact terminals 47 are arranged is projected through the buffer layer 46, and the sagging of the thin film probe sheet can be removed. Through the process described above, the sharp tip portions of the contact terminals can have the same height with the accuracy of ±2 μm over a large number of contact terminals 47.

In addition, in the thin film probe sheet according to the present invention, the formation region of the dummy metal film 12 which is formed to increase the terminal height in the vicinity of the contact terminals 47 has a size sufficiently larger than the tip diameter of the pressing member (pressing piece) 43 constituting the pressing mechanism. By doing so, the high contact terminals 47 having a sufficiently large spatial region formed in the measurement plane are formed, and furthermore, damages caused by above-described externally-introduced foreign substances are significantly reduced since the polyimide film which is the sheet base material covers the outer peripheral surfaces of the contact terminals.

Next, the electrical property inspection for the semiconductor chips to be inspected by using the probe card in which the thin film probe sheet according to the present invention is installed will be described with reference to FIG. 13.

FIG. 13 is a drawing showing the entire configuration of a semiconductor chip inspection system according to the present invention.

This inspection system comprises a sample support system 160 for supporting the semiconductor wafer 1, an inspection connecting system 120 which is brought into contact with the electrode pads 3 of the semiconductor wafer 1 to transmit electric signals, a drive control system 150 for controlling the operation of the sample support system 160, a temperature control system1 140 for controlling the temperature of the semiconductor wafer 1, and a tester 170 for inspecting the electrical properties of the semiconductor chip 2.

A large number of semiconductor ships 2 are arranged on the semiconductor wafer 1 and a plurality of minute electrode pads 3 to be connected to the outside are arranged at a narrow pitch on the surface of each semiconductor chip 2. The sample support system 160 is provided with a sample stage 162 placed almost horizontally for mounting the wafer 1, an elevation shaft 164 provided vertically so as to support the sample stage 162, an elevation drive unit 165 which moves up and down the elevation shaft 164, and an X-Y stage 167 which supports the elevation drive unit 165.

The X-Y stage 167 is fixed onto a chassis 166. The elevation drive unit 165 is composed of, for example, a stepping motor or the like. A turning mechanism is provided in the sample stage 162, which enables the rotational displacement of the sample stage 162 within the horizontal surface. The position of the sample stage 162 is determined by combining the operations of the X-Y stage 167, the elevation drive unit 165, and the turning mechanism.

The inspection connecting system 120 is placed above the sample stage 162. More specifically, the thin film probe sheet 44 and the wiring board 50 shown in FIG. 12 are positioned in parallel with the sample stage 162 and are opposed to the sample stage 162. Note that, in the fifth embodiment, the connecting terminal 50c is formed of a coaxial connector. The inspection connecting system 120 is connected to the tester 170 via a cable 171 connected to the connecting terminal 50c. The drive control system 150 is connected to the tester 170 via a cable 172. Also, the drive control system 150 sends a control signal to each drive unit of the sample support system 160 to control the operation thereof.

More specifically, the drive control system 150 is provided with a computer therein and controls the operation of the sample support system 160 in accordance with the progress information of the test operation of the tester 170 transmitted through the cable 172. Also, the drive control system 150 is provided with an operation unit 151 and receives the inputs of various instructions regarding the drive control, for example, the instruction for the manual operation.

The sample stage 162 is provided with a temperature controller 141 for heating purpose so as to perform the burn-in test of the semiconductor chip 2. The temperature control system 140 controls the temperature of the semiconductor wafer 1 mounted on the sample stage 162 by controlling the temperature controller 141 of the sample stage 162. Also, the temperature control system 140 is provided with an operation unit 151 to receive the instruction for the manual operation regarding the temperature control.

Hereinafter, operations of the inspection system will be described.

The semiconductor wafer 1 to be inspected is positioned and mounted on the sample stage 162. The optical images of a plurality of reference marks formed above the semiconductor wafer 1 are taken by an imaging device such as an image sensor or a TV camera to detect the positions of the plurality of reference marks based on the obtained image signals.

Based on the information of the detected positions of the reference marks, the information of the arrangement of the semiconductor chips 2 and that of the electrode pads 3 on the semiconductor chips 2 are confirmed in accordance with the type of the semiconductor wafer 1, and the two-dimensional positional information in the whole electrode pad group is calculated.

Furthermore, the optical images of the specific contact terminals in a large number of contact terminals 47 formed on the sheet or the optical images of a plurality of reference marks are taken by an imaging device such as an image sensor or a TV camera to detect the positions of the specific contact terminals or the plurality of reference marks. Based on the information described above, the two-dimensional positional information in the whole contact terminal group is calculated.

The drive control system 150 calculates the difference between the two-dimensional positional information in the whole contact terminal group and the two-dimensional positional information in the whole electrode pad group, and it controls the X-Y stage 167 and the turning mechanism based on the difference so that the group of the electrode pads 3 formed on a plurality of semiconductor chips arranged on the wafer 1 is positioned just below the group of a large number of provided contact terminals 47.

Thereafter, the drive control system 150 actuates the elevation drive unit 165 based on the gap between the surface of the region 44a of the thin film probe sheet and the semiconductor wafer 1 measured by a gap sensor provided on the sample stage 162, and it elevates the sample stage 162 until the whole surface of a large number of electrode pads 3 pushes up the contact terminals by several μm from the point where the surfaces of the electrode pads 3 come into contact with the tips of the contact terminals.

FIG. 14 shows the appearance of the inspection for the semiconductor chip 2 on which the electrode pads are arranged, by using the above-described semiconductor inspection system. In this manner, parallelism of all of the number of the contact terminal 47 is corrected in accordance with a whole surface of a large number of the electrode pads 3. Also, the variation in height of the contact terminals is absorbed by the buffer layer 46, and the contact terminals 47 are pressed into the electrode pads 3 at the small load (about 3 to 50 mN per pin), and thus, each of the contact terminals 47 is connected to each of the electrode pads 3 with a low resistance (0.01 to 0.1Ω).

When the burn-in test of the semiconductor chip 2 is performed in this state, the temperature control system 140 controls the temperature controller 141 of the sample stage 162 so as to control the temperature of the semiconductor wafer 1 mounted on the sample stage 162. Therefore, the thin film probe sheet is mainly made of flexible and preferably heat-resistant resin. In this embodiment, polyimide resin is used.

The operation power and the operation test signals are transmitted between the semiconductor chips formed on the semiconductor wafer 1 and the tester 170 through the cable 171, the wiring board 50, the thin film probe sheet and the contact terminals 47, and the electrical properties of the semiconductor chips are determined. The series of operations described above are executed for each of the semiconductor chips 2 formed on the semiconductor wafer 1 and the electrical properties and the like thereof are determined.

In the foregoing, the invention made by the inventors of the present invention has been concretely described based on the embodiments. However, it is needless to say that the present invention is not limited to the foregoing embodiments and various modifications and alterations can be made within the scope of the present invention.

Also, the representative aspects disclosed in the foregoing embodiments are as follows.

(1) A thin film probe sheet comprises: a plurality of contact terminals which come into electrical contact with electrodes disposed on a target to be inspected; individual wirings led out from the contact terminals via through holes of an insulating layer; and a plurality of peripheral electrodes which are electrically connected to the wirings and connected to electrodes of a wiring board, wherein a second metal film which is selectively removable relative to a first metal film which constitutes the contact terminals is disposed in a peripheral region around the plurality of contact terminals, and the second metal film is removed in a post process to provide gaps between the contact terminals, thereby increasing the height of the contact terminals.

(2) A thin film probe sheet comprises: a plurality of contact terminals which come into electrical contact with electrodes disposed on a target to be inspected; individual wirings led out from the contact terminals via through holes of an insulating layer; and a plurality of peripheral electrodes which are electrically connected to the wirings and connected to electrodes of a wiring board, wherein a base material sheet constituting the thin film probe sheet has a shape in which the regions at which the plurality of contact terminals are to be disposed are recessed in a concave manner from the surrounding region.

(3) A thin film probe sheet comprises: a plurality of contact terminals which come into electrical contact with electrodes disposed on a target to be inspected; individual wirings led out from the contact terminals via through holes of an insulating layer; and a plurality of peripheral electrodes which are electrically connected to the wirings and connected to electrodes of a wiring board, wherein, of a second metal film disposed in a peripheral region around the plurality of contact terminals, the parts which are formed above the contact terminals are selectively left, and the left second metal film is covered with a resin material constituting an insulating film.

(4) In the thin film probe sheet described in any one of (1) to (3), the contact terminal has a tip in a shape of a quadrangular pyramid or truncated pyramid.

(5) In the thin film probe sheet described in any one of (1) to (3), the contact terminal is made of at least one metal selected from a group including nickel, rhodium, palladium, iridium, ruthenium, tungsten, chromium, copper and tin or composed of laminated films of alloy of the metals.

(6) In the thin film probe sheet described in (1), the second metal film is made of at least one metal selected from nickel, copper and tin.

(7) A thin film probe sheet comprises: a plurality of contact terminals which come into electrical contact with electrodes disposed on a target to be inspected; individual wirings led out from the contact terminals via through holes of an insulating layer; and a plurality of peripheral electrodes which are electrically connected to the wirings and connected to electrodes of a multilayer wiring board, wherein, of a second metal film disposed in a peripheral region around the plurality of contact terminals, the metal film selectively left above the contact terminals has a shape of a polygonal or columnar pillar, and the depth or height of a recess of a spatial region in which the second metal film selectively removed relative to a first metal film which constitutes the contact terminals has been removed is sufficiently larger than the height of a quadrangular pyramid part or a truncated pyramid part formed in advance, thereby increasing the height of the contact terminals.

(8) The thin film probe sheet described in any one of (1) to (3) further comprises: a wiring board on which the thin film probe sheet is mounted; and pressing means for applying a pressing force.

(9) A probe sheet comprises: a plurality of contact terminals which come into electrical contact with electrodes disposed on a target to be inspected; wirings led out from the plurality of contact terminals; and an insulating film provided between the contact terminals and the wirings, wherein concavities are formed on one surface of the insulating film, and the contact terminals are formed in the concavities of the insulating film.

(10) In the probe sheet described in (9), the region in which the concavities are formed has a width larger than a width between the electrodes of the target to be inspected.

(11) In the probe sheet described in (9), the insulating film has protrusions in the region in which the concavities are formed, and the protrusions are disposed so as to cover the outer periphery of said contact terminals.

(12) In the probe sheet described in (11), the contact terminals and the wirings are electrically connected to each other via through holes provided in the protrusions of the insulating film.

(13) In the probe sheet described in any one of (9) to (12), a cross-sectional shape of the concavities is circular.

(14) In the probe sheet described in (9) to (12), the probe sheet includes wirings not electrically connected to the plurality of contact terminals.

(15) In the probe sheet described in (14), the wirings not electrically connected to the plurality of contact terminals are located in the region surrounded by the plurality of contact terminals in the probe sheet.

(16) In the probe sheet described in (15), the wirings not electrically connected to the plurality of contact terminals are disposed in a lattice pattern.

(17) A probe sheet comprises: a plurality of contact terminals which come into electrical contact with electrodes disposed on a target to be inspected; wirings led out from the plurality of contact terminals; and an insulating film provided between the contact terminals and the wirings, wherein bumps are formed on the surface of the insulating film on which the contact terminals are formed, and the thickness of the insulating film around the region in which the contact terminals are formed is smaller than that of the insulating film of the other portion.

(18) A probe sheet comprises: a plurality of contact terminals which come into electrical contact with electrodes disposed on a target to be inspected; wirings led out from the plurality of contact terminals; and an insulating film provided between the contact terminals and the wirings, wherein concavities are formed in the region of the insulating film around the region in which the contact terminals are formed.

(19) A semiconductor chip inspection system comprises: the thin film probe sheet described in any one of (9) to (12).

(20) The semiconductor chip inspection system described in (19) comprises: pressing means for applying a pressing force to the region of the probe sheet in which the concavities are formed.

(21) A manufacturing method of a semiconductor device comprises the steps of: fabricating circuits on a wafer to form semiconductor devices; inspecting electrical properties of the semiconductor devices; and dicing the wafer to separate the wafer into individual semiconductor devices, wherein, in the step of inspecting electrical properties of the semiconductor devices, the contact terminals formed in the concavities of an inspection system, which includes: the contact terminals to be brought into contact with electrodes of the semiconductor devices; wirings led out from the contact terminals; and an insulating film provided between the contact terminals and the wirings and having concavities wider than the width between the electrodes of the semiconductor devices provided on the one surface thereof, are brought into contact with the electrodes of the semiconductor devices, and then, inspection is performed.

(22) In the manufacturing method of a semiconductor device described in (21), in the step of inspecting electrical properties of the semiconductor devices, the electrodes of the semiconductor devices are brought into contact with the contact terminals by pressing means for applying a pressing force to the region of the insulating film in which the concavities are formed.

(23) In the manufacturing method of a semiconductor device described in (21) or (22), in the step of inspecting electrical properties of the semiconductor devices, the contact terminals whose outer periphery is covered with the insulating film of the protrusions formed in the concavity region of the insulating film are brought into contact with the electrodes of the semiconductor devices, and then, inspection is performed.

(24) In the manufacturing method of a semiconductor device described in (23), in the step of inspecting electrical properties of the semiconductor devices, electric signals are transmitted through the contact terminals in contact with the electrodes of the semiconductor devices, through holes formed in the protrusions of the insulating film, wirings electrically connected to the contact terminals via the through holes.

(25) In the manufacturing method of a semiconductor device described in (21), in the step of inspecting electrical properties of the semiconductor devices, the plurality of contact terminals disposed in a linear array are brought into contact with some of the plurality of electrodes formed in the semiconductor devices, and the plurality of contact terminals disposed in a zigzag manner are brought into contact with the other of the plurality of electrodes formed in the semiconductor devices, and then, the inspection is performed.

(26) In the manufacturing method of a semiconductor device described in (21), in the step of inspecting electrical properties of the semiconductor devices, owing to the concavities formed in the insulating film, the electrodes of the semiconductor devices and the contact terminals are brought into contact with each other without contact between the inspection system and the protrusions formed on the semiconductor devices, and then, the inspection is performed.

The effect obtained by the representative one of the inventions disclosed in this application will be briefly described as follows.

(1) Occurrence of damage due to the various foreign substances in the manufacturing processes of an object to be inspected such as a semiconductor chip can be reduced as much as possible.

(2) By virtue of above-mentioned (1), yield can be improved in a bonding process in the manufacture of a semiconductor device after the semiconductor chip inspection.

(3) In addition, without causing the damages by the generation of indentations and dust, stable connection can be realized with low resistance.

(4) Furthermore, the position accuracy of the tip portions of the contact terminals can be ensured, and semiconductor devices having narrow-pitch electrode structure can be reliably inspected.

(5) In addition, the life of the inspection system in which the thin film probe sheet is mounted is prolonged, and at the same time, production cost of semiconductor devices can be significantly reduced.

What is claimed is:

1. A manufacturing method of a semiconductor device comprising the steps of: fabricating circuits on a wafer to form semiconductor devices; inspecting electrical properties of the semiconductor devices; and dicing the wafer to separate the wafer into individual semiconductor devices,
wherein, in the step of inspecting electrical properties of the semiconductor devices, a plurality of contact terminals are formed in concavities of an inspection system, which includes: a plurality of contact terminals configured to be brought into contact with electrodes of said semiconductor devices; wirings led out from said plurality of contact terminals; and an insulating film provided between said plurality of contact terminals and said wirings and having said concavities which are wider than a width between the electrodes of said semiconductor devices provided on one surface thereof, are brought into contact with the electrodes of said semiconductor devices, and then, inspection is performed.

2. The manufacturing method of a semiconductor device according to claim 1,
wherein, in the step of inspecting electrical properties of said semiconductor devices, the electrodes of said semiconductor devices are brought into contact with said contact terminals by pressing means for applying a pressing force to the region of said insulating film in which the concavities are formed.

3. The manufacturing method of a semiconductor device according to claim 1,
wherein, in the step of inspecting electrical properties of said semiconductor devices, said contact terminals whose outer periphery is covered with the insulating film of protrusions formed in the concavities of said insulating film are brought into contact with the electrodes of said semiconductor devices, and then, inspection is performed.

4. The manufacturing method of a semiconductor device according to claim 3,
wherein, in the step of inspecting electrical properties of said semiconductor devices, electric signals are transmitted through said contact terminals in contact with the electrodes of said semiconductor devices, via wirings electrically connected to said contact terminals via through holes formed in the protrusions of said insulating film.

5. The manufacturing method of a semiconductor device according to claim 1,
wherein, in the step of inspecting electrical properties of said semiconductor devices, ones of said plurality of contact terminals disposed in a linear array are brought into contact with some of the plurality of electrodes formed in said semiconductor devices, and ones of said plurality of contact terminals disposed in a zigzag manner are brought into contact with others of said plurality of electrodes formed in said semiconductor devices, and then, the inspection is performed.

6. The manufacturing method of a semiconductor device according to claim 1,
wherein, in the step of inspecting electrical properties of said semiconductor devices, based on the configuration of the concavities formed in said insulating film, the electrodes of said semiconductor devices and said contact terminals are brought into contact with each other without contact between said inspection system and the protrusions formed on said semiconductor devices, and then, inspection is performed.

7. A manufacturing method of a thin film probe sheet, the thin film probe sheet comprising: a plurality of contact terminals configured to come into electrical contact with electrodes disposed on a target to be inspected; wirings led out from the contact terminals via through holes of an insulating layer; and a plurality of peripheral electrodes which are electrically connected to the wirings and connected to electrodes of a wiring board, said method comprising:
disposing a first metal film which constitutes said contact terminals in a peripheral region around the plurality of contact terminals:
disposing a selectively removable second metal film is disposed after the first metal film is disposed;
forming the wirings after the second metal film is disposed; and
removing the second metal film in a subsequent process to provide gaps between the contact terminals, thereby increasing a height of the contact terminals.

8. The manufacturing method of the thin film probe sheet according to claim 7,
wherein a base material sheet which constitutes the thin film probe sheet is formed to have a shape in which regions at which the plurality of contact terminals are to be disposed are recessed in a concave manner from a surrounding region.

9. The manufacturing method of the thin film probe sheet according to claim 7,
wherein, of the second metal film disposed in a peripheral region around the plurality of contact terminals, parts which are formed above the contact terminals are selectively left, and the left second metal film is covered with a resin material comprising an insulating layer.

10. The manufacturing method of the thin film probe sheet according to claim 7,
wherein each of the contact terminal includes a tip in a shape of a quadrangular pyramid or a truncated pyramid.

11. The manufacturing method of the thin film probe sheet according to claim 7,
wherein the contact terminals are comprised of at least one metal selected from a group including nickel, rhodium, palladium, iridium, ruthenium, tungsten, chromium, copper and tin or is comprised of laminated films of an alloy of the metals.

12. The manufacturing method of the thin film probe sheet according to claim 7,
wherein the second metal film is comprised of at least one metal selected from nickel, copper and tin.

13. The manufacturing method of the thin film probe sheet according to claim 7,
wherein, of the second metal film disposed in a peripheral region around the plurality of contact terminals, parts of the metal film selectively left above the contact terminals have a shape of a polygonal or columnar pillar, and a depth or height of a recess of a spatial region in which the first metal film which constitutes the contact terminals and the selectively removed second metal film have been formed is made sufficiently larger than a height of a quadrangular pyramid part or a truncated pyramid part formed in advance, thereby increasing the height of the contact terminals.

14. The manufacturing method of the thin film probe sheet according to claim 7,
wherein a wiring board on which the thin film probe sheet is mounted and a pressing mechanism for applying a pressing force are provided.

15. A manufacturing method of a semiconductor chip inspection system comprising the thin film probe sheet manufactured by the manufacturing method according to claim 7.
